(19) United States
(12) Patent Application Publication
(10) Pub. No.: US 2018/0182840 A1
(43) Pub. Date: Jun. 28, 2018

(54) DISPLAY PANEL BASED ON FLEXIBLE ORGANIC LIGHT-EMITTING DIODE, SEAMLESS SPLICING DISPLAY DEVICE AND METHOD FOR MANUFACTURING THE SAME

(71) Applicant: Shenzhen China Star Optoelectronics Technology Co., Ltd., Shenzhen, Guangdong (CN)

(72) Inventor: Bifen LIN, Shenzhen, Guangdong (CN)

(73) Assignee: Shenzhen China Star Optoelectronics Technology Co., Ltd., Shenzhen, Guangdong (CN)

(21) Appl. No.: 15/502,555

(22) PCT Filed: Dec. 29, 2016
(86) PCT No.: PCT/CN2016/113107

§ 371 Date: Feb. 8, 2017

(30) Foreign Application Priority Data
Dec. 21, 2016 (CN) 201611191966.3

(51) Int. Cl. H01L 27/32; H01L 51/00; H01L 51/52; H01L 51/56

(52) U.S. Cl. CPC H01L 27/3293; H01L 51/0097; H01L 51/5253; H01L 2227/326; H01L 51/003; H01L 2251/5315; H01L 2251/5338; H01L 51/56

(57) ABSTRACT

The present invention provides a display panel based on flexible organic light-emitting diode (OLED,) including a flexible substrate, an organic light-emitting layer and a thin-film packaging layer are arranged on the flexible substrate sequentially, a first splicing portion is formed on the first side of the flexible substrate by thinning process, a second splicing portion is formed on the second side of the flexible substrate by thinning process, a drive circuit and a control chip are arranged on a part of surface of the first splicing portion, the organic light-emitting layer extends to cover the second splicing portion. The present invention further provides a seamless splicing display device and a method for manufacturing the same.

### BACKGROUND OF THE INVENTION

### 1. Field of the Invention

The present invention relates to a technology of liquid crystal display, and more particularly, to a display panel based on flexible organic light-emitting diode (OLED,) a seamless splicing display device and a method for manufacturing the same.

### 2. The Related Arts

There are two kinds of display splicing, one is the traditional large screen display wall splicing hardware technology, the other is the seamless splicing technology using a projector to achieve by the edge blending technology. Wherein, the wall splicing hardware technology mainly includes: the digital light procession stitching (the gap is less than 0.5 mm,) the cathode ray tube stitching, plasma display panel stitching, and liquid crystal display stitching, but each above-mentioned splicing screen has gaps, the display effect is affected. The seamless splicing technology using the projector, edge fusion, and splicing device can achieve a true seamless splicing effect, but its cost is high, and its equipment is large.

### SUMMARY OF THE INVENTION

In order to solve deficiencies of prior art, the present invention provides a display panel based on flexible organic light-emitting diode (OLED) with good seamless splicing effect and low cost, a seamless splicing display device and a method for manufacturing the same.

In order to achieve the above-mentioned purpose, the present invention utilizes the following technical measurements by prior arts:

providing a display panel based on flexible OLED, including a flexible substrate, an organic light-emitting layer and a thin-film packaging layer are arranged on the flexible substrate sequentially, a first splicing portion is formed on the first side of the flexible substrate by thinning process, a second splicing portion is formed on the second side of the flexible substrate by thinning process, a drive circuit and a control chip are arranged on a part of surface of the first splicing portion, the organic light-emitting layer extends to cover the second splicing portion.

As one of the embodiments, the flexible substrate is a high molecular polymer, a metal sheet, or a glass.

As one of the embodiments, the organic light-emitting layer is a top emission type.

As one of the embodiments, the thin-film packaging layer is one or more of an acrylic resin, a transparent silicon nitride compound, and a silicon oxide.

As one of the embodiments, the second splicing portion of the third and the forth sides are also formed on the flexible substrate by thinning process.

The other purpose of the present invention is to provide a seamless splicing display device, wherein, a plurality of the spliced display panels based on flexible OLED is included, wherein the second splicing portion of the display panel is overlapped the first splicing portion of the adjacent display panel, and the ends of the second splicing portion is abutted against the adjacent display panel; the first splicing portion is bent toward the light exit direction.

As one of the embodiments, the second splicing portion is attached to the surface of the first splicing portion.

A further purpose of the present invention is to provide a method for manufacturing a seamless splicing display device, which comprises:

providing a glass substrate;

manufacturing a flexible substrate on the glass substrate and forming a first spliced portion and a second spliced portion;

arranging a top emission organic light-emitting device, a display circuit, and a drive circuit on the flexible substrate and extending the display circuit to the second splicing portion, arranging the display circuit in the first splicing portion;

packaging and performing the die bonding process in the first splicing portion;

peeling off the glass substrate;

splicing a first and a second display panels which are adjacent to each other, the second splicing portion of the first display panel is overlapped the bent first spliced portion of the second display panel; and

fixing two adjacent display panels.

As one of the embodiments, a method for manufacturing a flexible substrate on a glass substrate is: coating flexible substrate material on a glass substrate.

In the present invention, manufacturing a flexible substrate and forming a first spliced portion and a second spliced portion by thinning process, arranging a display circuit and a drive circuit on the first spliced portion and the second spliced portion respectively, and using thin-film packaging. By splicing the first and the second display panels which are adjacent to each other, so as to achieve the seamless splicing of the adjacent two display panels, and the cost is low, display effect is good.

### BRIEF DESCRIPTION OF DRAWINGS

FIG. 1 is an illustrational and configuration view of an embodiment made in accordance to a display panel in the present invention;

FIG. 2 is a structural illustration of an embodiment made in accordance to a flexible substrate in the present invention; and

FIG. 3 is an assembly structural illustration of an embodiment made in accordance to splice two adjacent display panels by flexible substrate in the present invention.

### DESCRIPTION OF PREFERRED EMBODIMENT

Technical implementation will be described below clearly and fully by combining with drawings made in accordance with an embodiment in the present invention.

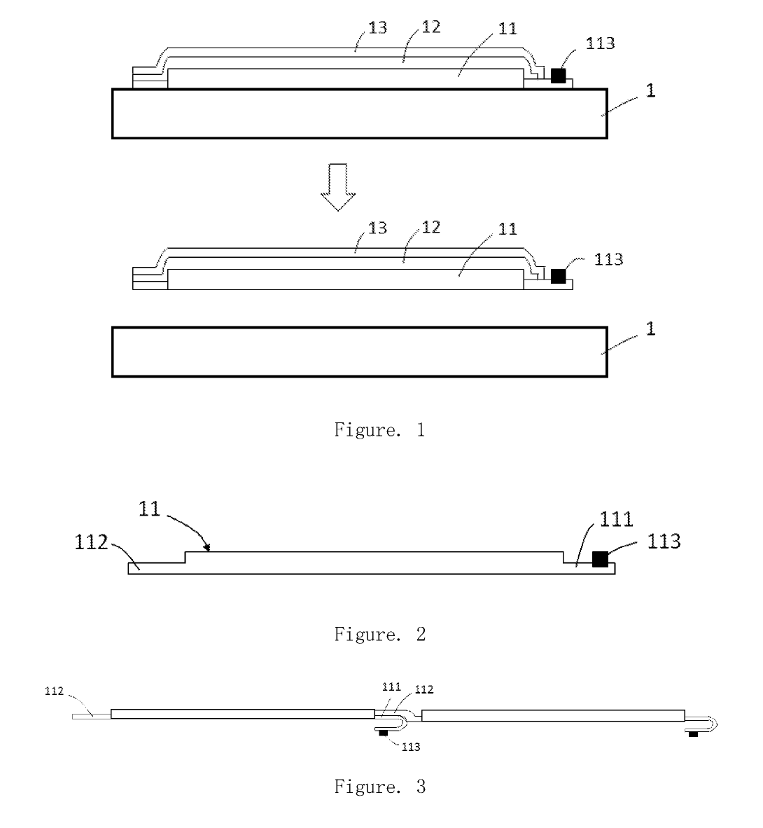

Referring to FIGS. 1 and 2, the embodiment of the present invention provides a display panel based on flexible OLED, which comprises a flexible substrate 11, an organic light-emitting layer 12 and a thin-film packaging layer 13 are arranged on the flexible substrate 11 sequentially, a first splicing portion 111 is formed on the first side of the flexible substrate 11 by thinning process, a second splicing portion 112 is formed on the second side of the flexible substrate 11 by thinning process, a drive circuit and a control chip 113 are arranged on a part of surface of the first splicing portion 111, the organic light-emitting layer 12 extends to cover the second splicing portion 112.

In the present embodiment, the second splicing portion 112 and the first splicing portion 111 are formed on the right and left sides of the flexible substrate 11. Specifically, a display circuit is arranged in a display region formed by the flexible substrate 11 and the second splicing portion 112, and arranging the drive circuit in the first splicing portion 111. The organic light-emitting layer 12 is a top emission type, this structure is not affected by the drive circuit in the bottom of the device, so it can effectively increase the aperture ratio and facilitate to integrate the device with the drive circuit in the bottom of the device.

The flexible substrate 11 may be a high molecular polymer, a metal sheet, or a glass. The thin-film packaging layer 13 is one or more of an acrylic resin, a transparent silicon nitride compound, and a silicon oxide.

The flexible substrate 11 structure of the present embodiment can be used for seamless splicing of two adjacent display panels. Of course, the other two sides of the flexible substrate 11 may also be formed the second splicing portion 112 by thinning process. Each display panel can combine with four adjacent display panels to be formed a combined display device.

A plurality of the spliced display panels can be combined to form a seamless splicing display device. Referring to FIG. 3, by bending the first splicing portion 111 toward the light exit direction, the first splicing portion 111 becomes to be a U-shape, the control chip 113 is located on the backside of the flexible substrate 11 with the first splicing portion 111. The second splicing portion 112 of one of the display panel is overlapped the first splicing portion 111 of the adjacent display panel, and the ends of the second splicing portion is abutted against the adjacent display panel, then splicing of the display device is completed. Since the upper second stitching portion 112 can display images, a true seamless splicing can be achieved. Further, since the first splicing portion 111 and the second splicing portion 112 are performed by thinning process, the display effect of the combined display device is not affected substantially.

The present invention provides a method for manufacturing a seamless splicing display device, wherein which comprises:

providing a glass substrate 1;

manufacturing a flexible substrate 11 on the glass substrate 1 and forming a first spliced portion 111 and a second spliced portion 112;

arranging a top emission organic light-emitting device, a display circuit, and a drive circuit on the flexible substrate 11 and extending the display circuit to the second splicing portion 112, arranging the display circuit in the first splicing portion 111;

packaging and performing the die bonding process in the first splicing portion 111;

peeling off the glass substrate 1 for forming a single display panel, so that the display panel manufacturing process is completed;

Subsequently, splicing a first and a second display panels which are adjacent to each other, the second splicing portion 112 of the first display panel is overlapped the bent first spliced portion 111 of the second display panel; and

Finally, fixing two adjacent display panels.

Wherein, preferably, manufacturing a flexible substrate 11 on the glass substrate 1 by coating flexible substrate material on a glass substrate 1. In other embodiments, the flexible substrate 11 may be formed on the glass substrate 1 by adhesion. The second splicing portion 112 is fixed to the surface of the first splicing portion 111 by sticking or screw fastening.

The two flexible substrates 11 are connected to an external controller via the control chip 113, By signals input from the controller, the spliced display device is controlled to achieve single screen display or large screen display selectively.

In the present invention, manufacturing a flexible substrate and forming a first spliced portion and a second spliced portion by thinning process, arranging a display circuit and a drive circuit on the first spliced portion and the second spliced portion respectively, and using thin-film packaging. By splicing the first and the second display panels which are adjacent to each other, so as to achieve the seamless splicing of the adjacent two display panels, and the cost is low, display effect is good.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A display panel based on flexible organic light-emitting diode, wherein including a flexible substrate, an organic light-emitting layer and a thin-film packaging layer arranged on the flexible substrate sequentially, a first splicing portion formed on the first side of the flexible substrate by thinning process, a second splicing portion formed on the second side of the flexible substrate by thinning process, a drive circuit and a control chip arranged on a part of surface of the first splicing portion, the organic light-emitting layer extending to cover the second splicing portion.

2. The display panel based on flexible organic light-emitting diode as recited in claim 1, wherein, the second splicing portion of the third and the forth sides are also formed on the flexible substrate by thinning process.

3. The display panel based on flexible organic light-emitting diode as recited in claim 1, wherein the flexible substrate is a high molecular polymer, a metal sheet, or a glass.

4. The display panel based on flexible organic light-emitting diode as recited in claim 3, wherein, the second splicing portion of the third and the forth sides are also formed on the flexible substrate by thinning process.

5. The display panel based on flexible organic light-emitting diode as recited in claim 1, wherein the organic light-emitting layer is a top emission type.

6. The display panel based on flexible organic light-emitting diode as recited in claim 5, wherein, the second splicing portion of the third and the forth sides are also formed on the flexible substrate by thinning process.

7. The display panel based on flexible organic light-emitting diode as recited in claim 1, wherein the thin-film packaging layer is one or more of an acrylic resin, a transparent silicon nitride compound, and a silicon oxide.

8. The display panel based on flexible organic light-emitting diode as recited in claim 7, wherein, the second splicing portion of the third and the forth sides are also formed on the flexible substrate by thinning process.

9. A seamless splicing display device, wherein, a plurality of spliced display panels based on flexible organic light-emitting diode is included, wherein based on flexible organic light-emitting diode: including a flexible substrate, an organic light-emitting layer and a thin-film packaging layer arranged on the flexible substrate sequentially, a first splicing portion formed on the first side of the flexible substrate by thinning process, a second splicing portion formed on the second side of the flexible substrate by thinning process, a drive circuit and a control chip arranged on a part of surface of the first splicing portion the organic light-emitting layer extending to cover the second splicing portion; the second splicing portion of the display panel overlapped the first splicing portion of the adjacent display panel, and the ends of the second splicing portion abutted against the adjacent display panel; the first splicing portion bent toward the light exit direction.

10. The seamless splicing display device as recited in claim 9, wherein the second splicing portion is attached to the surface of the first splicing portion.

11. The seamless splicing display device as recited in claim 9, wherein the flexible substrate is a high molecular polymer, a metal sheet, or a glass.

12. The seamless splicing display device as recited in claim 9, wherein the organic light-emitting layer is a top emission type.

13. The seamless splicing display device as recited in claim 9, wherein the thin-film packaging layer is one or more of an acrylic resin, a transparent silicon nitride compound, and a silicon oxide.

14. The seamless splicing display device as recited in claim 9, the second splicing portion of the third and the forth sides are also formed on the flexible substrate by thinning process.

15. A method for manufacturing a seamless splicing display device, wherein which comprises:
providing a glass substrate;
manufacturing a flexible substrate on the glass substrate and forming a first spliced portion and a second spliced portion;
arranging a top emission organic light-emitting device, a display circuit, and a drive circuit on the flexible substrate and extending the display circuit to the second splicing portion, arranging the display circuit in the first splicing portion;
packaging and performing the die bonding process in the first splicing portion;
peeling off the glass substrate;
splicing a first and a second display panels which being adjacent to each other, the second splicing portion of the first display panel overlapped the bent first spliced portion of the second display panel;
fixing two adjacent display panels.

16. The method for manufacturing a seamless splicing display device as recited in claim 15, wherein a method for manufacturing a flexible substrate on a glass substrate is: coating flexible substrate material on a glass substrate.

17. The method for manufacturing a seamless splicing display device as recited in claim 15, wherein the second splicing portion is attached to the surface of the first splicing portion.

18. The method for manufacturing a seamless splicing display device as recited in claim 15, wherein the flexible substrate is a high molecular polymer, a metal sheet, or a glass.

19. The method for manufacturing a seamless splicing display device as recited in claim 15, wherein the thin-film packaging layer is one or more of an acrylic resin, a transparent silicon nitride compound, and a silicon oxide.

20. The method for manufacturing a seamless splicing display device as recited in claim 15, the second splicing portion of the third and the forth sides are also formed on the flexible substrate by thinning process.
